(19) United States
(12) Patent Application Publication
(10) Pub. No.: US 2009/0288698 A1
(43) Pub. Date: Nov. 26, 2009

(54) PORTABLE SOLAR POWER SOURCE

(76) Inventor: Chi Gon Chen, Guang Zhou (CN)

Correspondence Address: CARSTENS & CAHOON, LLP, P O BOX 802334, DALLAS, TX, 75380, US

(21) Appl. No.: 12/537,817

(22) Filed: Aug. 7, 2009

Related U.S. Application Data
(62) Division of application No. 12/041,567, filed on Mar. 3, 2008.
(60) Provisional application No. 60/904,219, filed on Mar. 1, 2007.

(51) Int. Cl. H01L 31/042

(52) U.S. Cl. 136/244

(57) ABSTRACT

A portable solar power source is provided which will convert solar energy into electrical energy to provide electrical power to an array of devices normally accompanying those who enjoy being in outdoor areas or on rivers or lakes. The device is made to be portable by having wheels and a handle so that it may be pulled like a cart or wagon. The portable device of the present invention further includes one or more solar panels, which are deployed from a substantially horizontal position to a substantially vertical position with respect to the transport device. In the preferred embodiment the solar panels are double junction amorphous solar panels. Such panels have the greatest efficiency and produce electrical energy from light energy even if the solar panels are not in the direct sunlight.

### CROSS-REFERENCE TO RELATED APPLICATION

This application claims the benefit of and priority to a U.S. Provisional Patent Application No. 60/904,219 filed Mar. 1, 2007, the technical disclosure of which is hereby incorporated herein by reference.

### BACKGROUND OF THE INVENTION

1. Technical Field of the Invention

The present invention pertains to the conversion of light energy to electrical energy; more particularly the present invention pertains to a portable device to providing electrical energy to devices when traditional sources of electrical energy are not available.

2. Description of the Related Art

Beginning at the time when people started enjoying outdoor areas far away from their homes, the only convenient way of using items requiring electrical power, such as flashlights or radios, was to use batteries. If more electrical power was needed than could be provided by batteries or if electrical power was needed for an extended period of time, those needing power in outdoor settings or on rivers or lakes often used a gasoline engine powered mechanical generator. The gasoline engine on the mechanical generator provided the rotational power to turn a DC generator or an AC alternator thus producing electrical energy. In some situations, it was possible to bring a vehicle into an outdoor area so that the electrical accessory system on the vehicle could be used to provide low levels of electrical power. For example: many recreational vehicles or boats include electrical power take-offs to operate a variety of different devices enjoyed by those who spend time in recreational vehicle parks or on boats. Still other recreational vehicles or boats include on-board mechanical generators used to power the items needing electrical energy when the engine used to move the recreational vehicle or boat has been turned off.

While gasoline engine powered mechanical generators have proven to be a satisfactory solution for some, the transport of a mechanical generator to an outdoor area is prohibitively burdensome. In still other situations, the continued operation and maintenance of the gasoline engine on a mechanical generator requires the expertise of trained personnel as well as the time and materials needed to operate and service the mechanical generator. Accordingly, the use of mechanical generators has not gained acceptance by those going into outdoor areas for short periods of time or those not willing to carry a heavy mechanical generator long distances.

There remains a need in the art therefore for a portable device which can be taken into outdoor areas or to rivers or lakes that can be transported easily and will operate for extended periods of time to provide the electrical energy needed to operate equipment accompanying those going to outdoor areas, rivers or lakes.

### SUMMARY OF THE INVENTION

According to the present invention, a portable solar power source is provided which will convert solar energy into electrical energy to provide electrical power to an array of devices normally accompanying those who enjoy being in outdoor areas or on rivers or lakes.

The portable solar power source of the present invention is made to be portable by having wheels and a handle so that it may be pulled like a wagon. The portable device of the present invention farther includes one or more solar panels, which are deployed from a substantially horizontal position to a substantially vertical position with respect to the transport device. In the preferred embodiment the solar panels are double junction amorphous solar panels. Such panels have the greatest efficiency and produce electrical energy from light energy even if the solar panels are not in the direct sunlight.

The portable solar power source of the present invention may be connected to a group of electrical terminal boxes. Each terminal box contains a female socket similar to what is found in a residence. To utilize the power provided by the portable solar powered electrical energy generating system of the present invention, a user plugs a male connector, such as typically found on the end of a power cord from an appliance, into the female socket in the terminal box. In addition, a remote controller may be used to govern the flow of electrical energy.

A variety of different lighting systems may be connected to the terminal boxes. Because of the amount of electrical energy provided by double junction amorphous solar panels, enough electrical energy is available to for multiple light sets have multiple light fixtures. In addition, the present invention maybe used to power an electrical start on a lawnmower or operate a small refrigerator.

In a preferred embodiment of the portable solar power source of the present invention, rather than having two solar panels simply located on a framed cart, the portable solar power source employs a central console to which one or more solar panels are pivotally connected. The solar panels are pivot outwardly from the console into a substantially horizontal position to receive solar energy from the sun's rays. The central console may include a refrigerator or a storage compartment or the console may provide electrical power to additional sets of light fixtures.

### BRIEF DESCRIPTION OF THE DRAWINGS

A more complete understanding of the method and apparatus of the present invention may be had by reference to the following detailed description when taken in conjunction with the accompanying drawings, wherein:

FIG. 1a is a perspective view of an embodiment of the portable solar energy conversion device of the present invention in a first, folded position;

FIG. 1b is a perspective view of the embodiment of the portable solar energy conversion device shown in FIG. 1a in a second, opened position;

FIG. 1c is a perspective view of a variant of the embodiment of the portable solar energy conversion device shown in FIG. 1a in an opened position;

FIG. 2 is a view of the portable solar energy conversion device of the present invention connected to a group of electrical terminal boxes;

FIG. 3 is a view of the portable solar energy conversion device of the present invention connected to a group of electrical terminal boxes, wherein the terminal boxes are each connected to a series of different light fixtures;

FIG. 4 is a view of the portable solar energy conversion device of the present invention connected to a group of electrical terminal boxes, wherein the terminal boxes are each connected to a series of different light fixtures;

FIG. 5 is a view of the portable solar energy conversion device of the present invention connected to a group of electrical terminal boxes, wherein the terminal boxes are each connected to a series of different appliances and light fixtures;

FIG. 6a is a front perspective view of a second embodiment of the portable solar energy conversion device of the present invention in a first, folded position;

FIG. 6b is a front perspective view of the second embodiment of the portable solar energy conversion device shown in FIG. 6a in a second, opened position;

FIG. 6c is a rear perspective view of the second embodiment of the portable solar energy conversion device of the present invention shown in FIG. 6a;

FIG. 7a is a front perspective view of a variant of the second embodiment of the portable solar energy conversion device of the present invention in a first, folded position;

FIG. 7b is a front perspective view of the variant of the second embodiment of the portable solar energy conversion device shown in FIG. 7a in a second, opened position;

FIG. 7c is a rear perspective view of the variant of the second embodiment of the portable solar energy conversion device of the present invention shown in FIG. 7a;

Where used in the various figures of the drawing, the same numerals designate the same or similar parts. Furthermore, when the terms “top,” “bottom,” “first,” “second,” “upper,” “lower,” “height,” “width,” “length,” “end,” “side,” “horizontal,” “vertical,” and similar terms are used herein, it should be understood that these terms have reference only to the structure shown in the drawing and are utilized only to facilitate describing the invention.

All figures are drawn for ease of explanation of the basic teachings of the present invention only; the extensions of the figures with respect to number, position, relationship, and dimensions of the parts to form the preferred embodiment will be explained or will be within the skill of the art after the following teachings of the present invention have been read and understood. Further, the exact dimensions and dimensional proportions to conform to specific force, weight, strength, and similar requirements will likewise be within the skill of the art after the following teachings of the present invention have been read and understood.

### DETAILED DESCRIPTION OF THE INVENTION

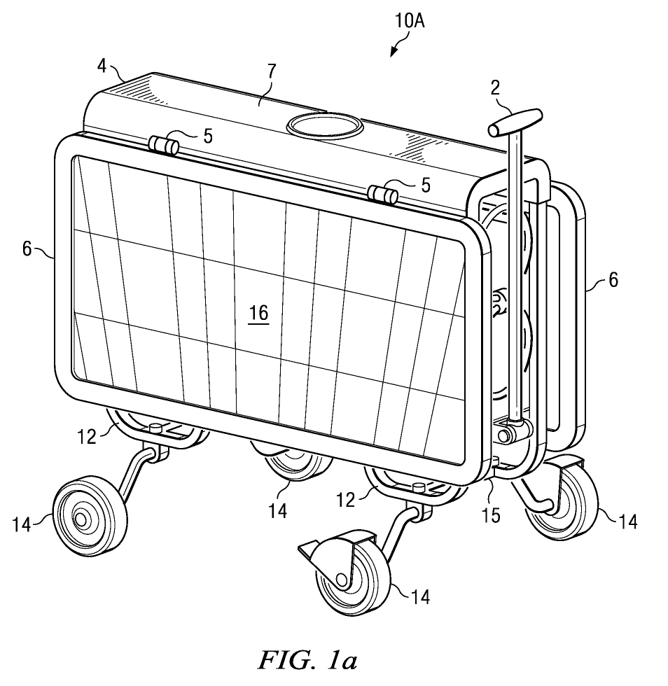

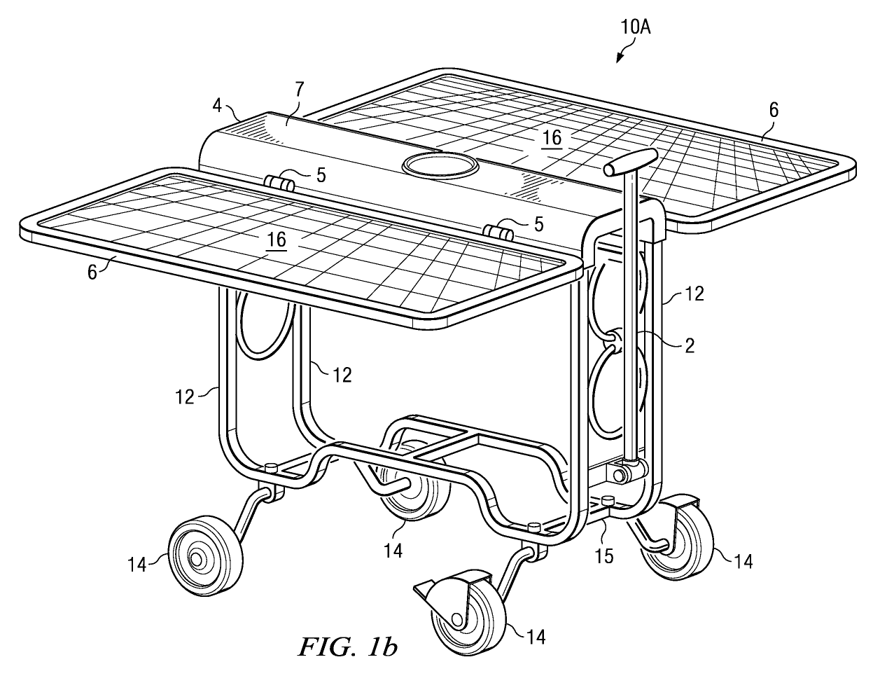

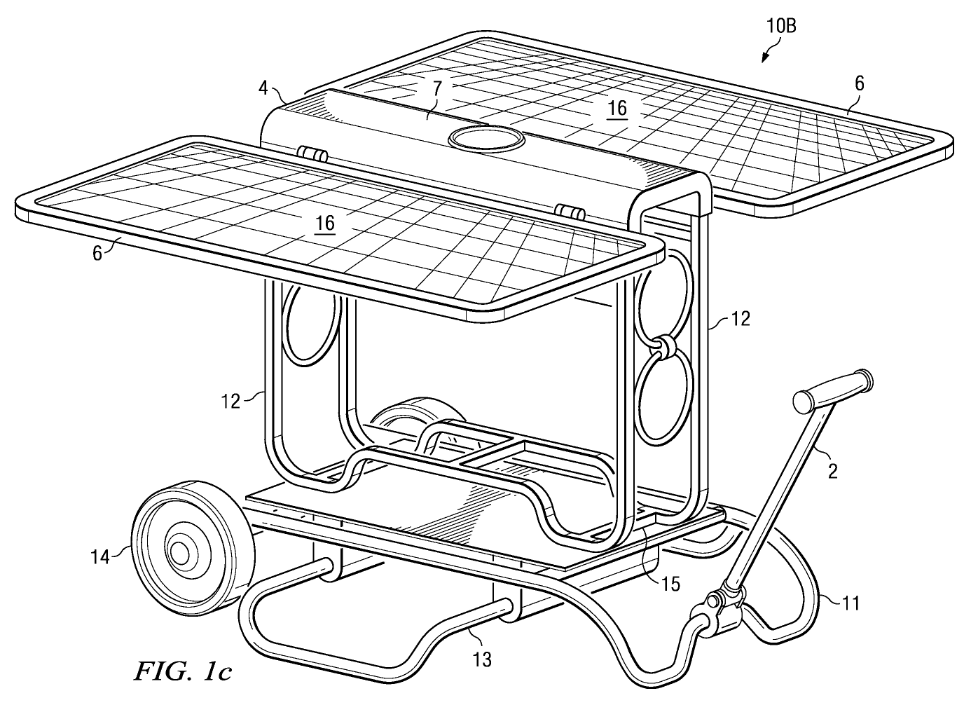

With reference to FIGS. 1a and 1b, an embodiment of the portable solar power source 10A of the present invention is depicted. The portable system 10A comprises one or more solar panels 16 pivotally mounted to a solar panel support 12. The solar panel support 12 is a rigid framework, constructed of a lightweight, high-strength tubular metal or plastic, and includes means for assisting in its transport across a variety of surfaces. For example, as depicted in FIGS. 1a and 1b, the transport means includes four wheel mechanisms 14 for assisting in the transport of the system 10A. It is understood that the wheel mechanisms 14 may be of fixed alignment or include caster mechanisms. In addition, the wheel mechanisms 14 may also include brake mechanisms for securing the portable system 10A in a fixed position.

The portable system 10A may further include a handle 2 to assist in transporting and positioning the system 10A to a desired location. The handle 2 is attached to the solar panel support 12. In a preferred embodiment, the handle 2 is pivotally attached to the solar panel support 12. Thus, the portable system 10A of the present invention is intuitively designed to be portable and includes wheels and a handle so that it may be pulled like a wagon.

The one or more solar panels 16 are each mounted in a frame housing 6 which supports and protects the solar panel 16 about its periphery. Each frame housing 6 is pivotally mounted to the solar panel support 12 by means of pivotal mounts 5. The pivotal mounts 5 may include a ratchet mechanism or friction mechanism for selectively and fixably positioning the solar panels at a specific angular alignment with respect to the solar panel support 12. In the preferred embodiment, the solar panels 16 are double junction amorphous solar panels. Such panels have the greatest efficiency and produce electrical energy from light energy even if the solar panels are not in the direct sunlight.

The solar panels 16 of the portable system 10A may deployed from a substantially vertical position to a substantially horizontal position with respect to the transport device. For example, the system 10A is shown in first, folded or stowed position in FIG. 1a, and in a second, unfolded or open position in FIG. 1b. It is understood that the portable system 10A may be moved whether in the stowed or opened positions.

The solar panels are electrically connected to an outlet 15 located near the front of the portable system 10A. In one embodiment, the outlet 15 merely comprises an electrical conduit, such as an electrical extension cord, hard wired to the solar panels 16 and extending from the front of the portable system 10A. In a preferred embodiment, the outlet 15 comprises a standard electrical outlet attached to the solar panel support 12.

The portable system 10A may also include cover assembly 4 is mounted to the top of the solar panel support 12. In addition to being a horizontal surface on which to store accessory items, the cover assembly 4 may also house a power storage device 7 for storing excess electrical energy generated from the solar panels 16. For example, in a preferred embodiment, the power storage device 7 comprises a battery. In such an embodiment, the power storage device 7 is electrically connected between the solar panels 16 and outlet 15.

With reference now to FIG. 1c, an alternate embodiment 10B of the previously described portable solar power source 10A of the present invention is depicted. The alternate embodiment 10B differs from the previously described embodiment 10A in only its means of the transport. The transport means of the portable system 10B includes two wheel mechanisms 14 mounted on a longitudinal secondary framework 11. The secondary framework 11 is attached and aligned with the solar panel support 12 so that the portable system 10B may be transported in a two-wheeled dolly cart fashion. The alternate embodiment 10B further includes a lateral framework 13 attached to the accessory framework 11 to improve the lateral stability of the portable system 10B. The alternate embodiment of the portable system 10B may further include a handle 2 attached to the accessory framework 11 to assist in transporting and positioning the system 10B to a desired location. In a preferred embodiment, the handle 2 is pivotally attached to the framework 11. Thus, the alternate embodiment of the portable system 10B of the present invention is intuitively designed to be portable and includes wheels and a handle so that it may be pulled like a dolly cart.

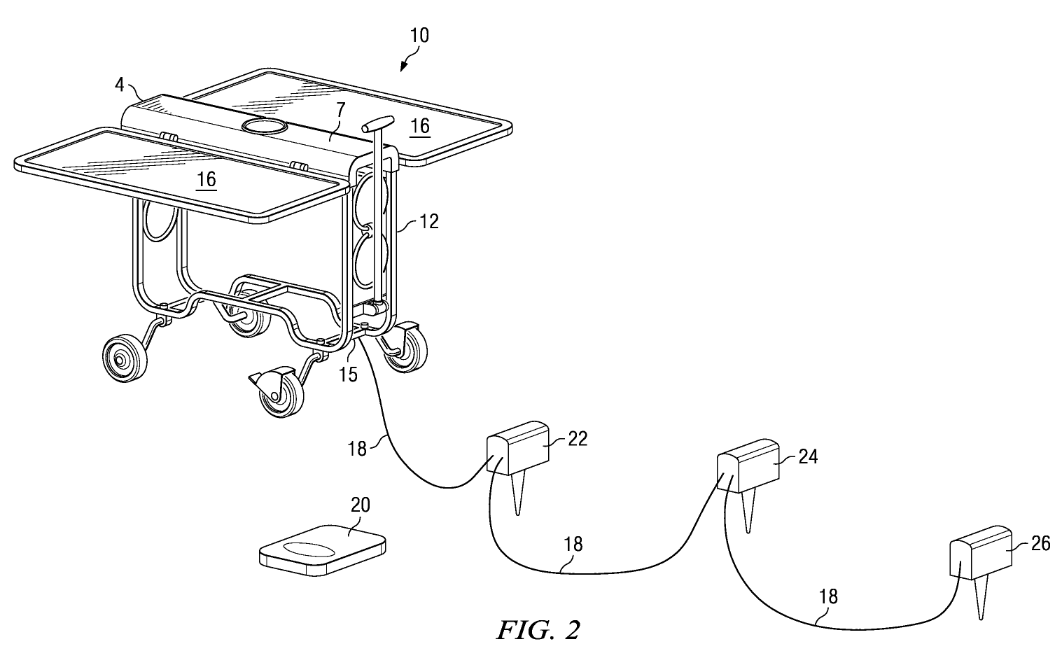

As shown in FIG. 2, the portable solar power source 10 of the present invention may be connected to a group of electrical terminal boxes 22, 24, 26. The terminal boxes 22, 24, 26 are connected to the portable solar power source 10 by means of an electrical conduit 18. As mentioned previously, the electrical conduit 18 may be hardwired into the outlet 15 of the portable solar power source 10. Alternatively, in a preferred embodiment, the outlet 15 comprises a standard electrical outlet attached to the solar panel support 12 and the electrical conduit 18 comprises standard electrical wiring selectively attached in series to the outlet 15 and to the various electrical terminal boxes 22, 24, 26. Each terminal box 22, 24, 26 contains a female socket similar to what is found in a residence. To utilize the electrical power provided by the portable solar power source 10, a user plugs a male connector, such as typically found on the end of a power cord from an appliance, into the female socket in each terminal box. In addition, a remote controller 20 may be used to govern the flow of electrical energy to each of the terminal boxes 22, 24, 26.

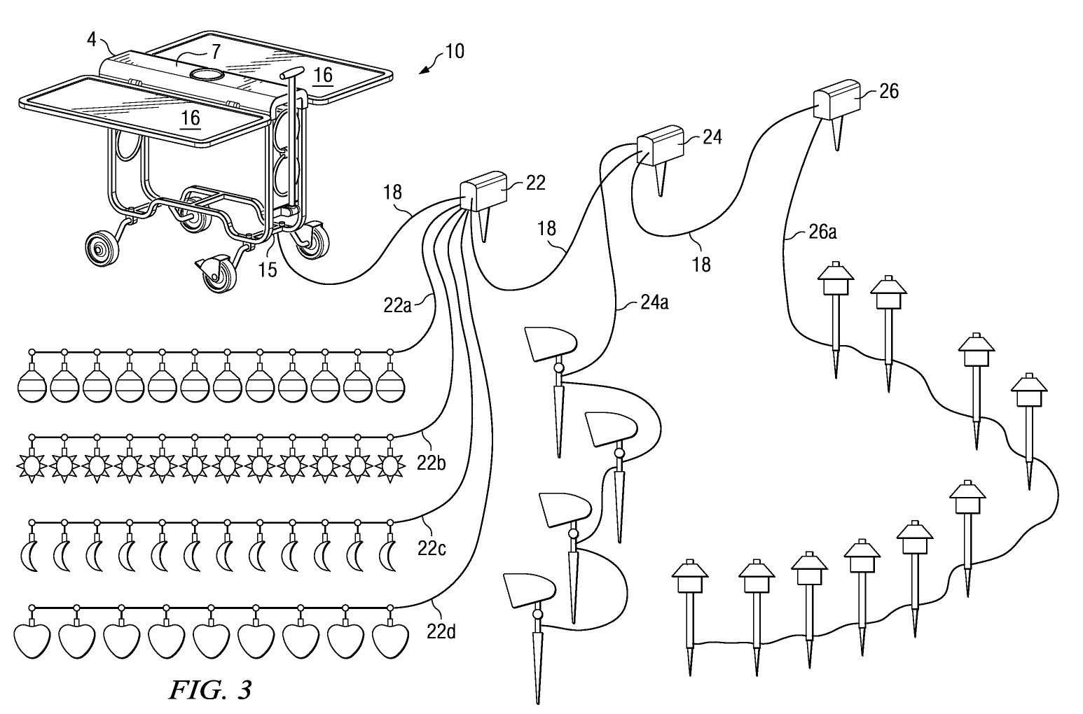

With reference now to FIGS. 3-5, a variety of different lighting systems may be connected to the terminal boxes. Because of the amount of electrical energy provided by double junction amorphous solar panels, enough electrical energy is available to for multiple light sets have multiple light fixtures. For example, in FIG. 3, the portable solar power source 10 supplies electricity to a first terminal box 22, which in turn supplies electricity to four strings of low-wattage LED decorative lights 22a, 22b, 22c, 22d. A second terminal box 24 provides electricity to a string of low-wattage LED spot lights 24a, while a third terminal box 26 supplies electricity to a string of low-wattage LED landscaping lights 26a.

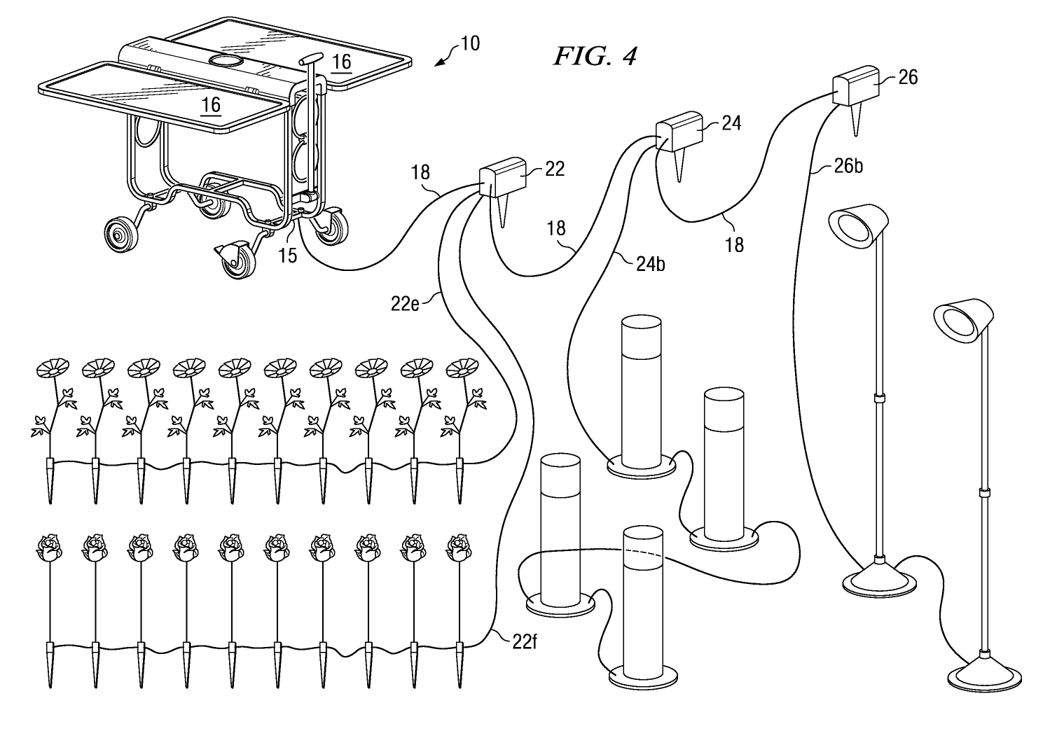

Alternatively, as shown in FIG. 4, the portable solar power source 10 supplies electricity to a first terminal box 22, which in turn supplies electricity to two strings of low-wattage LED decorative lights 22e, 22f. The second terminal box 24 provides electricity to a string of low-wattage LED walk way lights 24b, while the third terminal box 26 supplies electricity to a two low-wattage LED flood lights 26b.

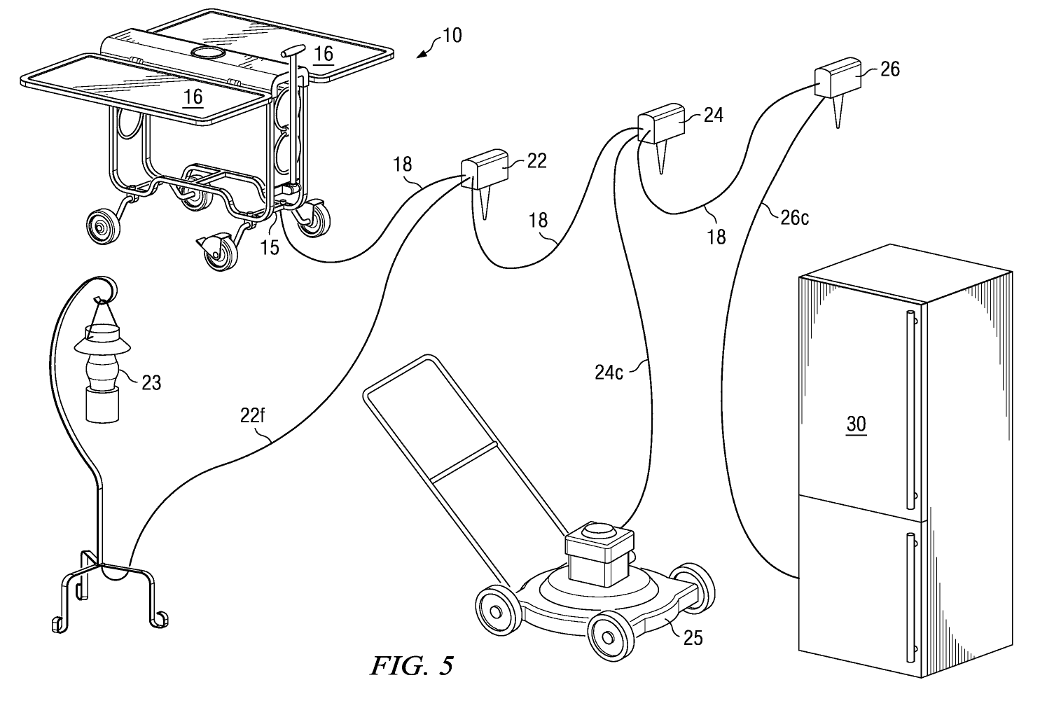

Because of the amount of electrical energy provided by double junction amorphous solar panels, enough electrical energy is available to for even higher wattage applications. Thus, as depicted in FIG. 5, portable solar power source 10 can supply electricity to a higher wattage lamp 23 via the first terminal box 22. In addition, the portable solar power source 10 can supply electrical power to an electrical start on a lawnmower 24 via secondary electrical conduit 24c connected to the second terminal box 24. Likewise, the portable solar power source 10 can supply electrical power to a small refrigerator 30 via electrical conduit 26c attached to the third terminal box 26. Thus, a wide variety of useful electrical devices and mechanism can be powered using the portable solar power source 10 of the present invention.

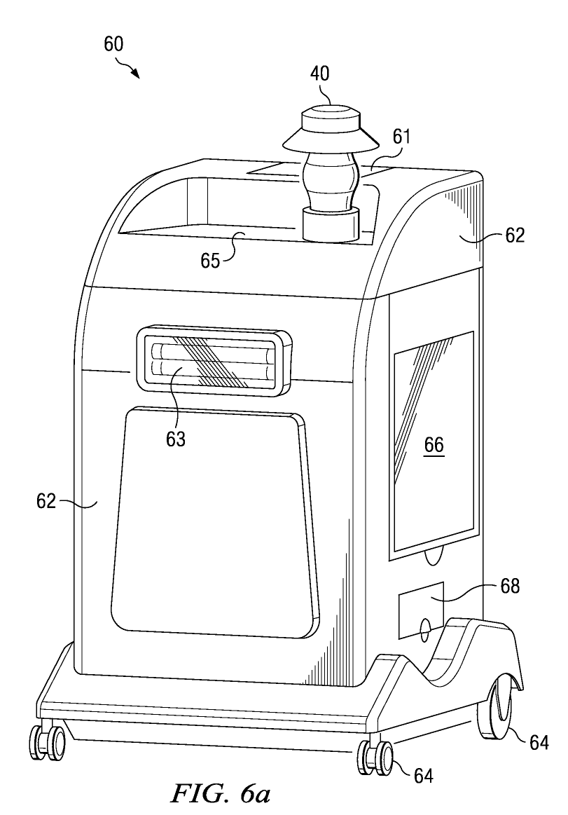

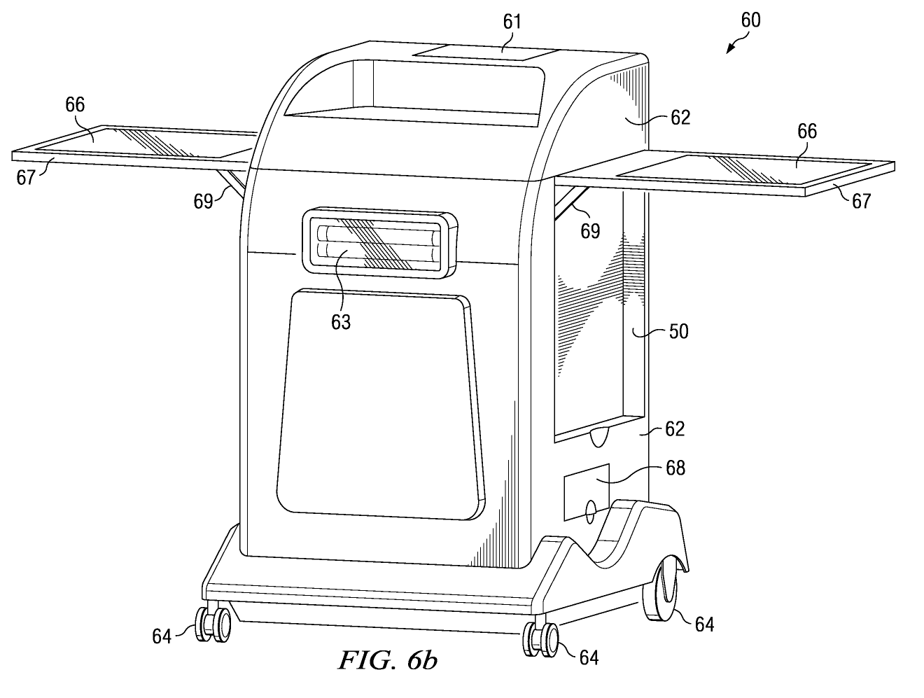

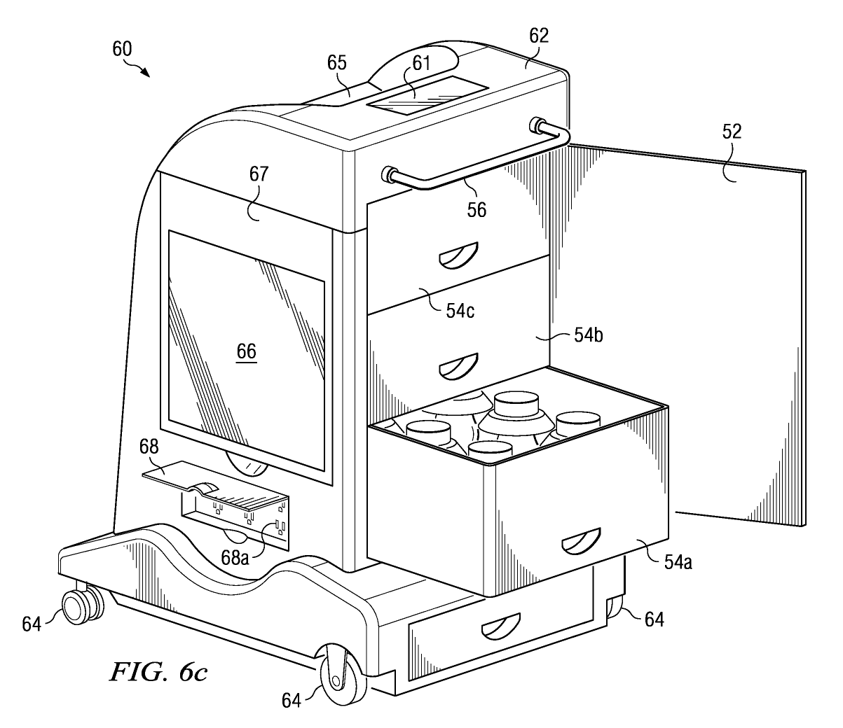

With reference now to FIGS. 6a-6c, a preferred embodiment of the portable solar power source 60 is depicted. Rather than comprising a framed cart device, the depicted embodiment includes a solar panel support of monocoque construction to which one or more solar panels are pivotally connected. For example, as shown in the Figures, the portable solar power source 60 includes a central solar panel support console 62 having two pivotally mounted solar panels 66. The central solar panel support console 62 may be constructed of a lightweight, high-strength metal, plastic or any composite combination thereof.

The central solar panel support console 62 is a monocoque structure mounted on four wheel mechanisms 64, which assist in moving of the portable solar power source 60 to a desired location. The central console 62 may include a horizontal shelf 65 formed in its top and an integral electrical light 63 attached to the front. The central console 62 further includes an inset portion 50 formed in the sides of the monocoque structure for receiving each solar panel 66 mounted in its housing frame 67. The inset portion 50 is dimensioned so that the solar panel 66 and its attached housing frame 67 are flush to the side of the side of the central console when configured in the vertical or stowed position as shown in FIG. 6a. As shown in FIG. 6b, the solar panels 66 pivot outwardly from the central console 62 into a substantially horizontal position to receive solar energy from the sun's rays.

The housing frames 67 are pivotally mounted to the sides of the central console 62 by means of pivotal mounts 69. The pivotal mounts 69 may include a ratchet mechanism or friction mechanism for fixably positioning the solar panels at a specific angular alignment with respect to the central console 62. In the preferred embodiment, the solar panels 66 are double junction amorphous solar panels. Such panels have the greatest efficiency and produce electrical energy from light energy even if the solar panels are not in the direct sunlight. The solar panels are electrically connected to the electrical outlet panel 68a located on the side of the depicted portable solar power source 60.

In addition, the central console 62 further includes an electrical outlet panel 68a located on a side. The electrical outlet panel 68a may include one or more electrical outlets. The electrical outlets can be dimensioned and configured to receive standard electrical plugs or to receive specialized plugs. A panel cover 68 is provided to protect the outlet panel 68a from dirt and moisture. The central console 62 may also house a power storage device 61 for storing excess electrical energy generated from the solar panels 66. For example, in a preferred embodiment, the power storage device 61 comprises a battery. In such an embodiment, the power storage device 61 is electrically connected between the solar panels 66 and outlet panel 68a.

As shown in FIG. 6c, the central console 62 may further include a refrigerated space 54a, 54b, 54c behind a door 52 pivotally attached to the back of the central console. It is understood that the refrigerated space may comprise a single open space or the multiple drawers 54a, 54b, 54c depicted. It is understood that the central console 62 may contain appropriate mechanisms for operating a vapor-compression refrigeration cycle utilizing electrical energy from the solar panels. Alternatively, the central console 62 may be constructed of an insulated material such that the refrigeration effect is affected by means of ice or other cold material. Thus, drawers 54a, 54b, 54c may be constructed to hold ice or other temporal cold material for providing refrigeration like a standard ice cooler. Another alternative embodiment, would comprise a combination of the two previously described embodiments, that is an ice cooler having some refrigeration effect generated utilizing the electricity generated by the solar panels 66. A handle bar 56 may also be attached to the back of the central console 62.

A variety of different lighting systems may be connected to the outlet panel 68a. Because of the amount of electrical energy provided by double junction amorphous solar panels, enough electrical energy is available to for multiple light sets have multiple light fixtures.

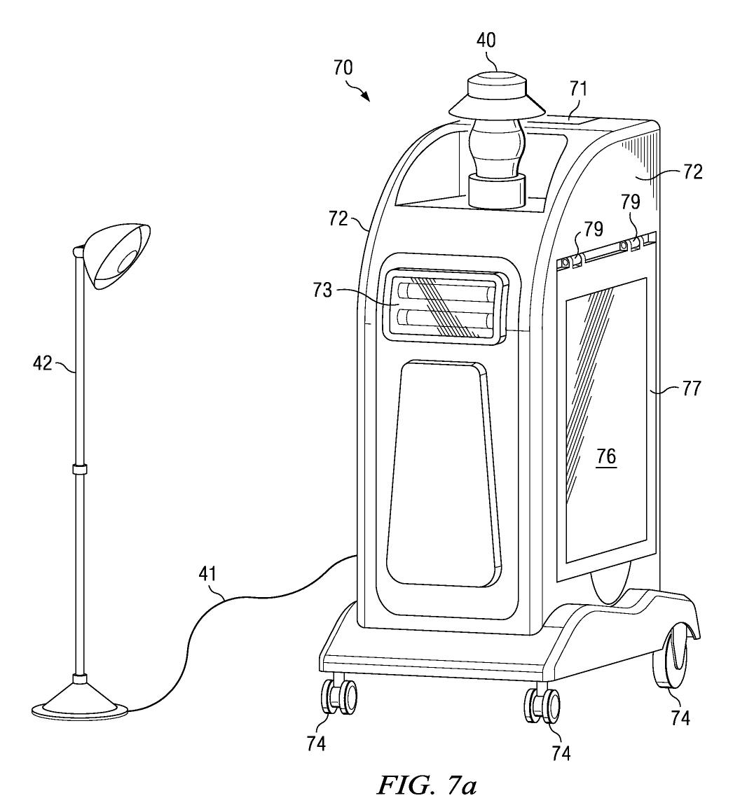

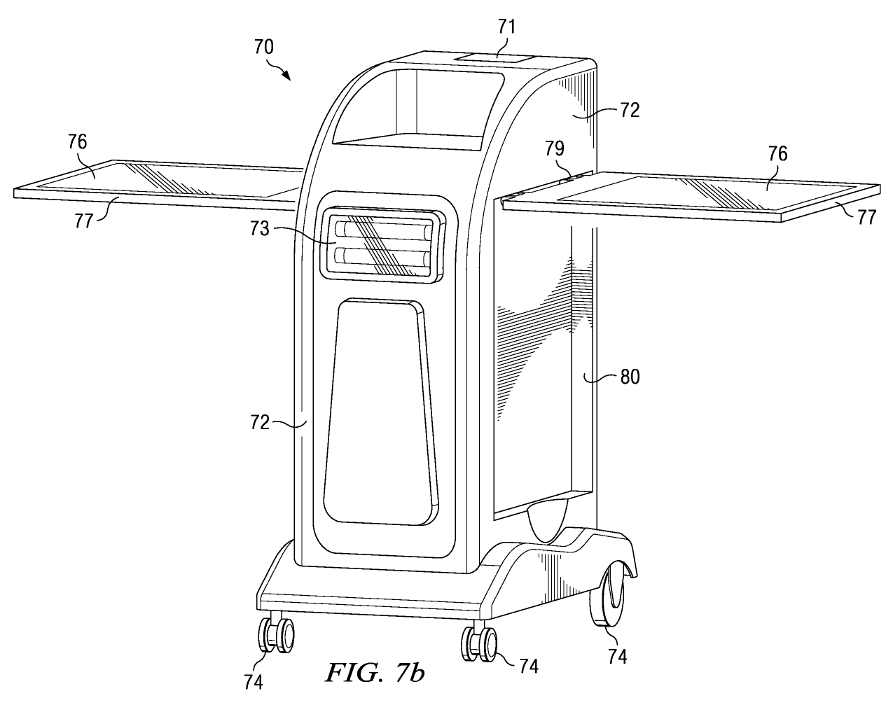

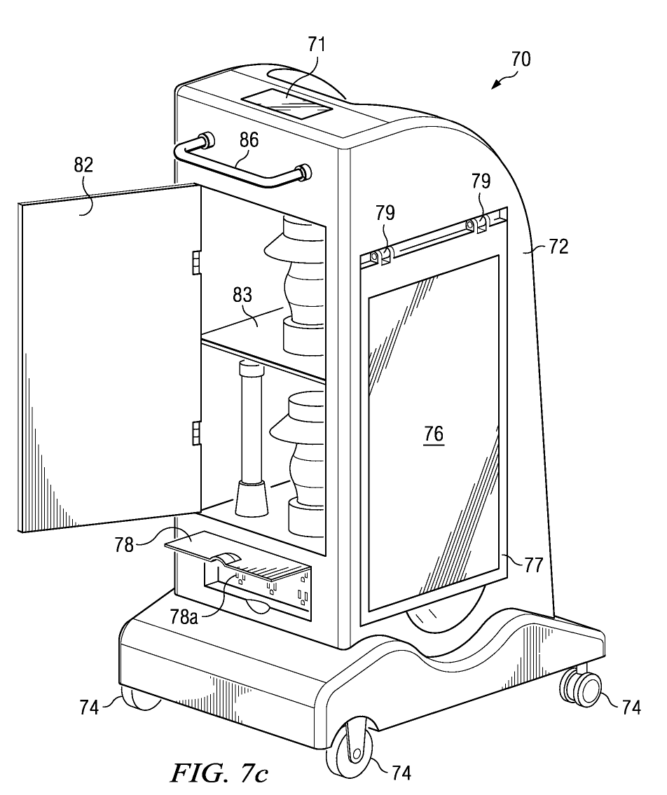

With reference now to FIGS. 7a-7c, a variant of the preferred embodiment of the portable solar power source 70 is depicted. As previously described, rather than comprising a framed cart device, the depicted variant of the embodiment also includes a central console of monocoque construction to which one or more solar panels are pivotally connected. For example, as shown in the Figures, the portable solar power source 70 includes a central solar panel support console 72 having two pivotally mounted solar panels 76. The central solar panel support console 72 may be constructed of a lightweight, high-strength metal, plastic or any composite combination thereof.

The central solar panel support console 72 is a monocoque structure mounted on four wheel mechanisms 74, which assist in moving of the portable solar power source 70 to a desired location. The central console 72 may include a horizontal shelf formed in its top and an integral electrical light 73 attached to the front. The central console 72 further includes an inset portion 80 formed in the sides of the monocoque structure for receiving each solar panel 76 mounted in its housing frame 77. The inset portion 80 is dimensioned so that the solar panel 76 and its attached housing frame 77 are flush to the side of the side of the central console when configured in the vertical or stowed position as shown in FIG. 7a. As shown in FIG. 7b, the solar panels 76 pivot outwardly from the central console 72 into a substantially horizontal position to receive solar energy from the sun's rays.

The housing frames 77 are pivotally mounted to the sides of the central console 72 by means of pivotal mounts 79. The pivotal mounts 79 may include a ratchet mechanism or friction mechanism for selectively and fixably positioning the solar panels at a specific angular alignment with respect to the central console 72. In the preferred embodiment, the solar panels 76 are double junction amorphous solar panels. Such panels have the greatest efficiency and produce electrical energy from light energy even if the solar panels are not in the direct sunlight. The solar panels are electrically connected to the electrical outlet panel 78a located on the back of the depicted portable solar power source 70.

In addition, the central console 72 further includes an electrical outlet panel 78a located on the back of the console 72. The electrical outlet panel 78a may include one or more electrical outlets. The electrical outlets can be dimensioned and configured to receive standard electrical plugs or to receive specialized plugs. A panel cover 78 is provided to protect the outlet panel 78a from dirt and moisture. The central console 72 may also house a power storage device 71 for storing excess electrical energy generated from the solar panels 76. For example, in a preferred embodiment, the power storage device 71 comprises a battery. In such an embodiment, the power storage device 71 is electrically connected between the solar panels 76 and outlet panel 78a.

As shown in FIG. 7c, the central console 72 may further include a storage space 83 behind a door 82 pivotally attached to the back of the central console 72. As depicted, the storage space 83 may include and be divided by one or more horizontal shelves. A handle bar 86 may also be attached to the back of the central console 72 to assist in moving the console 72.

A variety of different lighting systems (e.g., light 42) may be connected to the outlet panel 78a via an electrical conduit 41. Because of the amount of electrical energy provided by double junction amorphous solar panels, enough electrical energy is available to for multiple light sets have multiple light fixtures.

It will now be evident to those skilled in the art that there has been described herein an improved portable solar power source. Although the invention hereof has been described by way of a preferred embodiment, it will be evident that other adaptations and modifications can be employed without departing from the spirit and scope thereof. The terms and expressions employed herein have been used as terms of description and not of limitation; and thus, there is no intent of excluding equivalents, but on the contrary it is intended to cover any and all equivalents that may be employed without departing from the spirit and scope of the invention.

1. A portable system for providing electrical energy in outdoor areas, said system comprising:
one or more solar panels pivotally attached to a solar panel support; said solar panel support having a monocoque construction and wheels mounted thereon to enable transport;
means for converting light energy received by said one or more solar panels into electrical energy;
at least one electrical outlet for providing electrical energy to a device requiring electrical power for operation.

2. (canceled)

3. (canceled)

4. (canceled)

5. (canceled)

6. The portable system of claim 1, wherein said one or more solar panels are pivotally attached said solar panel support by means of pivotal mounts.

7. The portable system of claim 6, wherein said pivotal mounts include a ratchet mechanism for selectively and fixably positioning said solar panels at a specific angular alignment with respect to the solar panel support.

8. The portable system of claim 6, wherein said pivotal mounts include a friction mechanism for selectively and fixably positioning said solar panels at a specific angular alignment with respect to the solar panel support.

9. (canceled)

10. The portable system of claim 1, wherein said solar panel support includes an inset portion for receiving said solar panel.

11. The portable system of claim 1, wherein said solar panel support is constructed of metal.

12. The portable system of claim 1, wherein said solar panel support is constructed of high-strength plastic.

13. The portable system of claim 1, wherein said solar panel support includes an integral light fixture.

14. The portable system of claim 1, wherein said solar panel support comprises a refrigerated compartment.

15. The portable system of claim 1, wherein said solar panel support includes an outlet panel.

16. The portable system of claim 1, wherein said solar panel support comprises an internal storage compartment.
